(19) United States
(12) Patent Application Publication
(10) Pub. No.: US 2010/0051102 A1
(43) Pub. Date: Mar. 4, 2010

(54) SOLAR CELL MODULE

(75) Inventor: Chung-Jyh LIN, YongKang City (TW)

Correspondence Address: BIRCH STEWART KOLASCH & BIRCH, PO BOX 747, FALLS CHURCH, VA, 22040-0747, US

(73) Assignee: AUSSMAK OPTOELECTRONIC CORP., YongKang City (TW)

(21) Appl. No.: 12/539,902

(22) Filed: Aug. 12, 2009

(30) Foreign Application Priority Data
Aug. 29, 2008 (TW) 097133229
Mar. 20, 2009 (TW) 098109233

(51) Int. Cl. H01L 31/00

(52) U.S. Cl. 136/259

(57) ABSTRACT

A solar cell module has a chamber and includes a solar cell device, a gel/fluid, and a light-focusing unit. The solar cell device is disposed in the chamber, and the gel/fluid is filled in the chamber. The light-focusing unit focuses at least one part of the external light to the solar cell device.

### CROSS REFERENCE TO RELATED APPLICATIONS

This Non-provisional application claims priority under 35 U.S.C. §119(a) on Patent Application No(s). 097133229 and 098109233 filed in Taiwan, Republic of China on Aug. 29, 2008 and Mar. 20, 2009, the entire contents of which are hereby incorporated by reference.

### BACKGROUND OF THE INVENTION

1. Field of Invention

The present invention relates to a solar cell module.

2. Related Art

Due to the issues of energy exhaustion and environmental protection, the renewal energy and its applications have become the important subjects. Since the solar energy is one of the most easily retrieved renewal energies, there are many manufacturers spending many efforts on the solar cell technology.

Referring to FIG. 1, a conventional solar cell module 1 includes a solar cell device 11 and a light-permeable housing 12 for accommodating the solar cell device 11.

Thus, the external light L is capable of penetrating through the light-permeable housing 12 to induce the photovoltaic conversion phenomenon in the solar cell device 11, thereby enabling the solar cell module 1 to generate electric energy.

However, if the solar cell device 11 is not disposed on the traveling path of the external light L, which passes through the light-permeable housing 12, the external light L can not induce the photovoltaic conversion phenomenon of the solar cell device 11 and will leave the light-permeable housing 12 directly. This will cause the poor light utilization of the solar cell module 1. Besides, if the external light L is the sunlight, the solar cell device 11 can receive the light energy as well as the heat energy. The photovoltaic conversion efficiency of the solar cell device 11 may be affected if the long-term sunlight is provided without proper heat dissipation.

Therefore, it is an important subjective of the present invention to provide a solar cell module that has improved light utilization and heat dissipation.

### SUMMARY OF THE INVENTION

In view of the foregoing, the present invention is to provide a solar cell module having improved light utilization and heat dissipation.

To achieve the above, the present invention discloses a solar cell module, which has a chamber and includes a solar cell device, a gel/fluid and a light-focusing unit. The solar cell device is disposed in the chamber, and the gel/fluid is filled in the chamber. The light-focusing unit focuses at least one part of the external light to the solar cell device.

In addition, the present invention also discloses a solar cell module including a carrier, a light-focusing unit and a solar cell device. The light-focusing unit and the carrier form a chamber, in which the solar cell device is disposed. The light-focusing unit focuses at least one part of the external light to the solar cell device, and the carrier and the light-focusing unit are relatively moveable.

As mentioned above, the solar cell module of the present invention includes a light-focusing unit for focusing at least one part of the external light to the solar cell device, thereby improving the undesired situation that the external light passes through the solar cell module without inducing the photovoltaic conversion in the solar cell device. Thus, the light utilization of the solar cell module can be increased. In addition, the solar cell module of the present invention has a chamber filled with the gel or fluid, so that the heat generated by the solar cell device can be dissipated through the gel or fluid so as to enhance the heat dissipating efficiency of the solar cell device.

Moreover, the solar cell module of the present invention includes the carrier and light-focusing unit, which are relative moveable with respective to the incident direction of the light, so that the light utilization of the solar cell module can be further increased.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic view showing a conventional solar cell module;

FIG. 2 is a schematic view showing a solar cell module according to a first embodiment of the present invention;

FIGS. 3A and 3B are schematic views showing different solar cell modules according to the first embodiment of the present invention;

FIG. 4 is a schematic view showing a solar cell module according to a second embodiment of the present invention;

FIG. 5 is a schematic view showing another solar cell module according to the second embodiment of the present invention;

FIG. 6 is a schematic view showing a solar cell module according to a third embodiment of the present invention;

FIG. 7 is a schematic view showing another solar cell module according to the third embodiment of the present invention;

FIG. 8 is a schematic view showing a solar cell module according to a fourth embodiment of the present invention;

FIGS. 9A and 9B are schematic views showing different solar cell modules according to the fourth embodiment of the present invention;

FIG. 10 is a schematic view showing a solar cell module according to a fifth embodiment of the present invention;

FIG. 11 is a schematic view showing the solar cell module according to the second embodiment of the present invention, wherein the solar cell module has a Fresnel lens;

FIG. 12 is a schematic view showing the solar cell module according to the third embodiment of the present invention, wherein the solar cell module has a Fresnel lens; and

FIGS. 13 and 14 are schematic views showing the solar cell modules according to the fourth embodiment of the present invention, wherein the solar cell modules have a Fresnel lens.

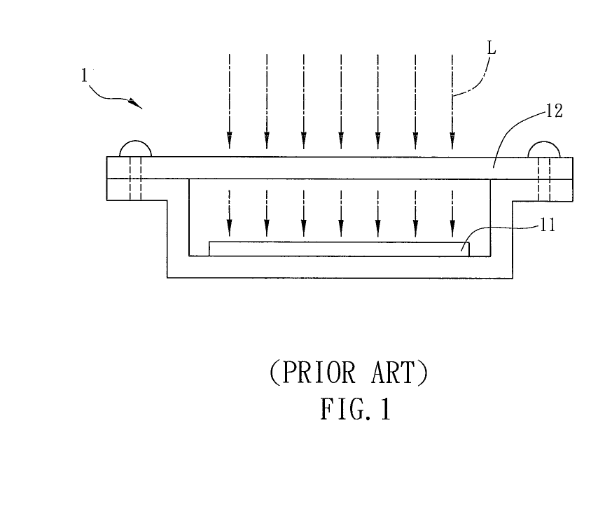

### DETAILED DESCRIPTION OF THE INVENTION

The present invention will be apparent from the following detailed description, which proceeds with reference to the accompanying drawings, wherein the same references relate to the same elements.

### First Embodiment

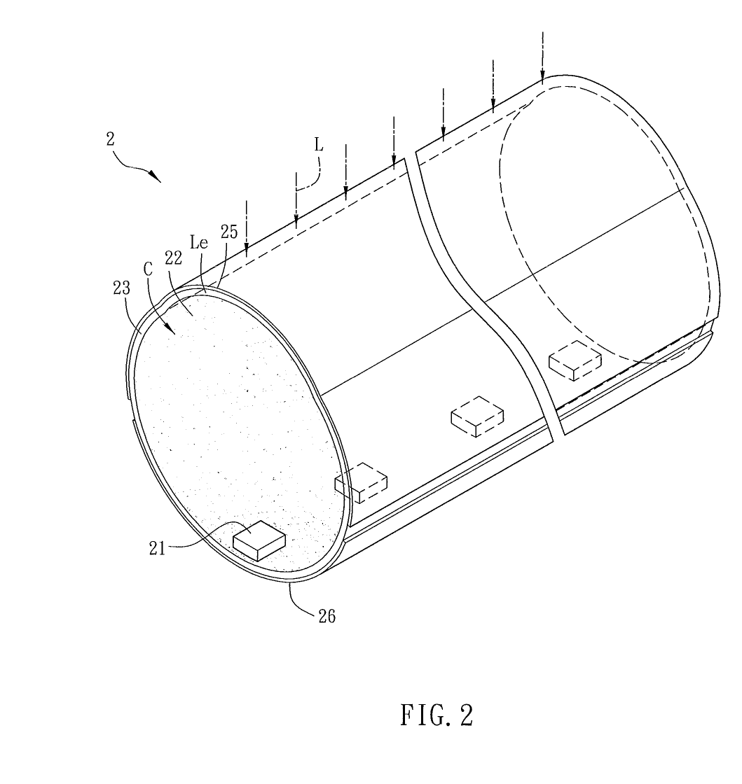

FIG. 2 is a schematic view of a solar cell module 2 according to a first embodiment of the present invention. With reference to FIG. 2, the solar cell module 2 has a chamber C and includes a solar cell device 21, a gel/fluid 22, and a light-focusing unit 23. In this embodiment, the chamber C is positioned in the light-focusing unit 23.

The solar cell device 21 can be directly disposed on the light-focusing unit 23 and located in the chamber C. In this case, the light-focusing unit 23 has a circuit layer disposed on the inner surface thereof (not shown) for outputting the electric energy generated by the solar cell device 21. In general, the solar cell device 21 is also called a photovoltaic cell device such as a thin film solar cell device, a photovoltaic diode device (PVD), a mono-crystalline silicon solar cell device, a poly-crystalline silicon solar cell device, a compound semiconductor solar cell device, or a dye-sensitized solar cell device. In the present embodiment, the solar cell device 21 can be a single solar cell device, a multilayer structure, or a solar cell panel formed by a solar cell array. In FIG. 2, the solar cell module 2 includes a plurality of semiconductor solar cell devices 21 (e.g. GaAs thin-film solar cell devices).

The gel/fluid 22 is filled in the chamber C. In particular, the gel/fluid 22 may completely or partially fill the chamber C. For example, the gel/fluid 22 may partially fill the chamber C to just cover the solar cell device 21. The gel can be melted, semisolid, elastic or solidified, and the fluid can be gas (e.g. air or inert gas) or liquid (e.g. oil or solvent). For example, the fluid can be mineral oil, silicon oil, ethanol or methanol. In the present embodiment, the chamber C is an airtight chamber and is filled with, for example but not limited to, gas. To be noted, the two ends of the light-focusing unit 23, which are not sealed as shown in FIG. 2, are for illustrating the internal structure of the light-focusing unit 23 only.

In this embodiment, the light-focusing unit 23 is a tube, and it is at least partially light-permeable. In addition, the light-focusing unit 23 has at least one lens structure Le, which is located at a light input side of the light-focusing unit 23 and integrally formed with the tube. To be noted, the light-focusing unit 23 may further include additional elements such as epoxy (not shown) to seal the two ends of the tube, thereby forming an airtight space inside the chamber C.

The lens structure Le of the light-focusing unit 23 can focus at least one part of the external light L to the solar cell device 21, so that the undesired situation that the external light L passes through the solar cell module 2 without inducing the photovoltaic conversion in the solar cell device 21 can be improved, thereby increasing the light utilization of the solar cell module 2. In addition, if the magnification factor of the light-focusing unit 23 is properly designed, the area of the focus spot of the external light L focused by the light-focusing unit 23 can be minimized. Accordingly, the area of the solar cell device 21 can be also minimized so as to decrease the material cost of the solar cell module 2. Herein, the small-size solar cell device 21 can be a photovoltaic diode. Moreover, the gel/fluid 22 is filled in the chamber C for facilitating the conduction of the heat generated by the solar cell device 21, thereby enhancing the heat dissipation effect of the solar cell device 21.

In addition, the solar cell module 2 may further include an anti-reflective layer 25, which is disposed on a partial surface of the light-focusing unit 23. In this embodiment, the anti-reflective layer 25 is disposed on the outer surface of the light-focusing unit 23, which is also the surface that the external light L passes through to enter the solar cell module 2. The anti-reflective layer 25 can be a single-layer structure or a multi-layer structure, which has a plurality of films with decreased refractive indexes from the surface to outside. To be noted, it is possible to dispose another anti-reflective layer on the inner surface of the light-focusing unit 23 to increase the amount of light entering into the light-focusing unit 23. Accordingly, the anti-reflective layer 25 can prevent the external light L from being reflected by the light-focusing unit 23 before entering into the chamber C, thereby enhancing the light utilization of the solar cell module 2.

In order to increase the light utilization and heat dissipation effect, the solar cell module 2 may further include a reflective layer 26, which is at least partially disposed on a surface of the light-focusing unit 23. Therefore, the external light L from the top can be reflected by the reflective layer 26 and then enter the chamber C.

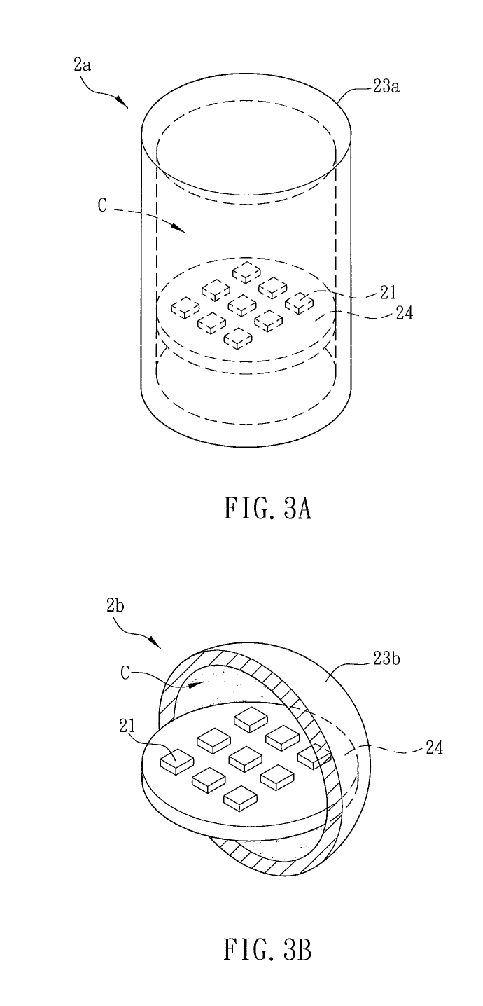

With reference to FIGS. 3A and 3B, the light-focusing unit of the solar cell module, such as the light-focusing unit 23a and 23b, may have different structures. In addition, the solar cell module 2a/2b may further include a carrier 24 disposed in the chamber C, and the solar cell device 21 is disposed in the carrier 24. The material of the carrier 24 may include glass, quartz, ceramic materials, polymer, plastic or metal. In addition, the carrier 24 may have a pure function of carrying an object, or it may be a circuit board such as a glass circuit board, a printed circuit board, or a ceramic circuit board. According to the carrier 24, such as a glass circuit board, the electric energy generated by the solar cell device 21 can be outputted.

The light-focusing unit can be a pillar such as the light-focusing unit 23a of FIG. 3A or a sphere such as the light-focusing unit 23b of FIG. 3B. The various shapes of the light-focusing unit may broaden the application range of the solar cell module 2a/2b.

To be noted that the solar cell module 2 may further include a driving assembly, which is also called a solar tracking system (not shown). The driving assembly can drive the light-focusing unit 23, 23a or 23b of the solar cell module to move corresponding to the angle of the external light L (sunlight), thereby precisely utilizing the external light L to enhance the photovoltaic conversion efficiency.

### Second Embodiment

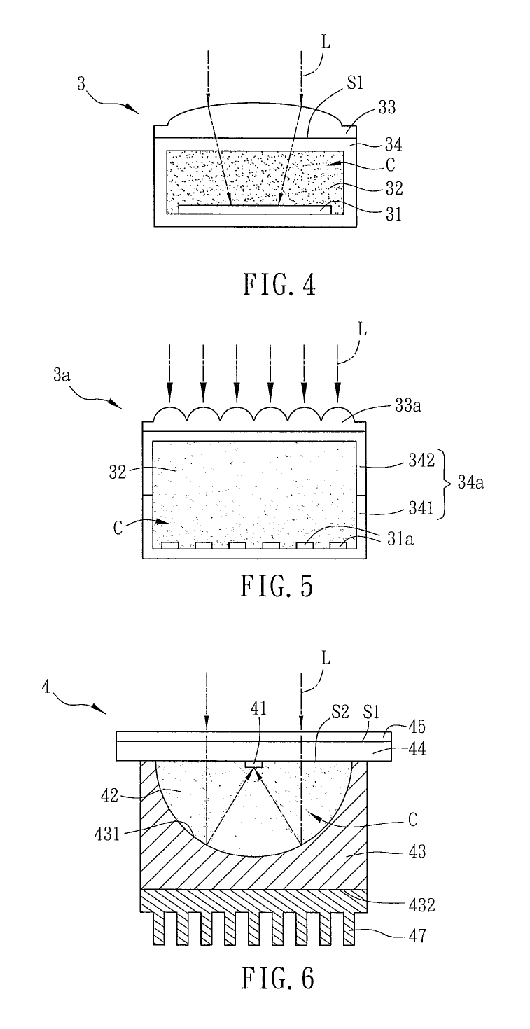

FIG. 4 is a schematic view of a solar cell module 3 according to a second embodiment of the present invention. Referring to FIG. 4, the solar cell module 3 has a chamber C and includes a solar cell device 31, a gel/fluid 32, a light-focusing unit 33, and a carrier 34. In this embodiment, the carrier 34 is disposed in the chamber C, and the chamber C can be an airtight chamber or an opening chamber.

The solar cell device 31 is disposed on the carrier 34 and is located in the chamber C. In this embodiment, the chamber C is an airtight chamber, and the chamber C is fully filled with the fluid 32. In addition, the solar cell module 3 may be further connected to a motor (not shown) to pump the fluid 32 to the outside of the solar cell module 3 through a pipe and then return to the chamber C of the solar cell module 3 after cooling. This can further enhance the heat dissipation efficiency.

The light-focusing unit 33 can focus at least one part of the external light L to the solar cell device 31, and it is disposed the inside or the outer surface S1 of the carrier 34. Otherwise, the light-focusing unit 33 and the carrier 34 may have a gap therebetween. In this embodiment, the light-focusing unit 33 is disposed on an outer surface S1 of the carrier 34 for example. The structure of the light-focusing unit 33 can be a convex lens or a Fresnel lens for focusing the external light L, which is originally parallel light beams, on the solar cell device 31. Herein, the light-focusing unit 33 is a convex lens. The solar cell devices 31 and the convex lenses may be configured corresponding to each other one by one, or several solar cell devices 31 correspond to one single convex lens. To be noted, if the solar cell devices 31 are arranged in one dimension, two dimensions or an array, the convex lenses, for example, can also be arranged in one dimension, two dimensions or an array.

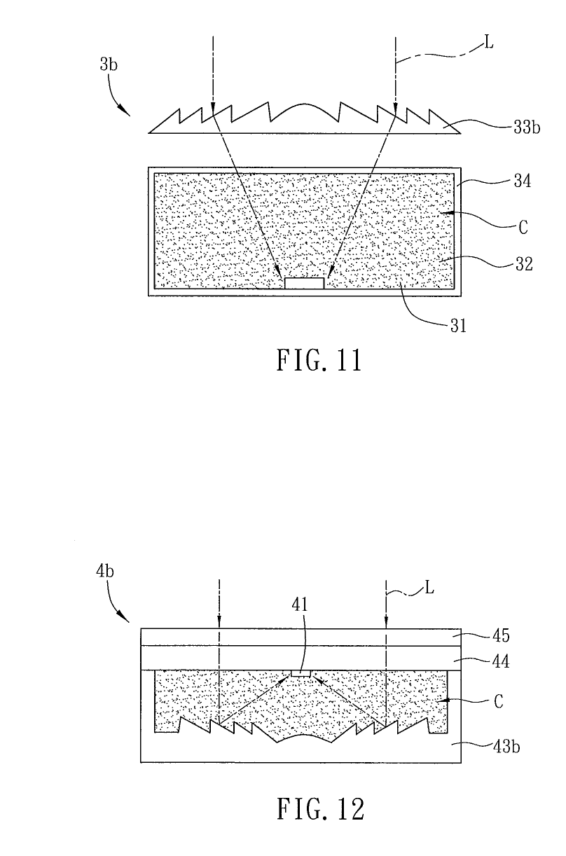

As shown in FIG. 11, a light-focusing unit 33b of the solar cell module 3b is a Fresnel lens, and the light-focusing unit 33b and the carrier 34 have a gap therebetween. In this case, the Fresnel lens is used instead of the convex lens, so that the thickness of the light-focusing unit 33b can be decreased.

The carrier 34 is at least partially light-permeable and is made of glass, quartz, sapphire, plastic or polymer. In practice, the carrier 34 is preferably made of glass or quartz, which can stand the UV light. According to different demands, the shape of the carrier 34 can be an ellipsoid, a sphere, a cube or a rectangular solid. Besides, the carrier 34 may further include a circuit layer for outputting the electric energy generated by the solar cell device 31.

Therefore, the light-focusing unit 33 can focus at least one part of the external light L to the solar cell device 31, thereby improving the undesired situation that the external light L passes through the solar cell module 3 without inducing the photovoltaic conversion in the solar cell device 31. Thus, the light utilization of the solar cell module 3 can be increased. In addition, the chamber C is filled with the gel/fluid 32, so that the heat generated by the solar cell device 31 can be dissipated through the gel/fluid 32 so as to enhance the heat dissipating efficiency of the solar cell device 31.

In addition, the solar cell module 3 further includes a driving assembly, such as a solar tracking system, which can drive the light-focusing unit 33 and the carrier 34 of the solar cell module 3 to move corresponding to the angle of the external light L (sunlight), thereby precisely utilizing the external light L to enhance the photovoltaic conversion efficiency.

FIG. 5 is a schematic view showing another solar cell module 3a according to the second embodiment of the present invention. The different between the solar cell modules 3 and 3a is in that the carrier 34a of the solar cell module 3a is composed of at least two sub-carriers 341 and 342, a plurality of solar cell devices 31a are disposed on the sub-carrier 341, and the light-focusing unit 33a includes a plurality of convex lens structures.

The sub-carriers 341 and 342 can be combined by, for example but not limited to, locking, screwing, adhering, welding or hooking. To be noted, since the screw, adhesive or hooking elements may not firmly combine the sub-carriers 341 and 342, the chamber C formed by the sub-carriers 341 and 342 may be not perfectly airtight. In addition, since the sub-carriers 341 and 342 are separately manufactured and then combined to form the carrier 34a and chamber C, the difficulty for installing the solar cell device 31a in the carrier 34a can be decreased, thereby increasing the manufacturing performance and reducing the manufacturing cost.

In this embodiment, the solar cell module 3a includes a plurality of solar cell devices 31a, which are disposed on the sub-carrier 341 and are photovoltaic diodes. If the magnification factor of the light-focusing unit 33a is properly designed, the area of the focus spot of the external light L focused by the light-focusing unit 33a can be reduced. Accordingly, the area of the solar cell devices 31a can be also reduced so as to decrease the material cost of the solar cell module 3a. With reference to FIGS. 4 and 5, the area of each solar cell device 31a of FIG. 5 is smaller than that of the solar cell device 31 of FIG. 4.

### Third Embodiment

FIG. 6 is a schematic view of a solar cell module 4 according to a third embodiment of the present invention. Referring to FIG. 6, the solar cell module 4 has a chamber C and includes a solar cell device 41, a gel/fluid 42, a light-focusing unit 43 and a carrier 44.

The chamber C is formed by combining the carrier 44 and the light-focusing unit 43, which can be combined by locking, screwing, adhering, welding or hooking. The solar cell device 41 is disposed in the carrier 44, and the carrier 44 is at least partially light-permeable. Thus, the external light L may pass through the carrier 44.

The light-focusing unit 43 has a reflective surface 431 for reflecting a part of the external light L, which passes through the carrier 44, to the solar cell device 41. For example, the light-focusing unit 43 can be a metal housing, an alloy housing, or a plastic housing, which is coated with a reflective layer. In this embodiment, the light-focusing unit 43 is a metal housing. To be noted, the reflective surface 431 can be a parabolic surface, so that the external light L passing through the carrier 44 can be focused on the solar cell device 41. Herein, the curvature and shape of the reflective surface 431 is not limited and is determined for the purpose of reflecting the external light L to the solar cell device 41. For example, as shown in FIG. 12, a light-focusing unit 43b of a solar cell module 4b is a reflective Fresnel lens, and the reflective surface 431b is disposed on the inner surface of the light-focusing unit 43b, which is also the place disposed with the Fresnel pattern. Alternatively, the light-focusing unit 43b may be a housing with a reflective Fresnel lens for focusing the light to the solar cell device 41.

The material of the carrier 44 may include glass, quartz, plastic or polymer, and the shape thereof can be different according to different demands. For example, the carrier 44 may be a plate, or it may have a concave portion for disposing the solar cell device 41. In addition, the light-focusing unit 43 and the carrier 44 may be made of the flexible material based on different demands, thereby facilitating the installation of the solar cell module 4.

As mentioned above, the reflective solar cell module 4 includes the light-focusing unit 43 with the reflective surface 431 for precisely focusing the external light L to the solar cell device 41. Accordingly, the light utilization of the solar cell module 4 can be greatly increased. Besides, the external light L passes only the carrier 44 and is then reflected and focused by the light-focusing unit 43, so that the loss of the external light L after passing through many media can be reduced.

In addition, the solar cell module 4 may farther include an anti-reflective layer 45, which is disposed on a partial surface of the carrier 44. In this embodiment, the anti-reflective layer 45 is disposed on the outer surface S1 of the carrier 44, which is also the surface that the external light L passes through to enter the solar cell module 4. In order to increase the amount of light entering into the carrier 44, it is possible to dispose another anti-reflective layer on the inner surface S2 of the carrier 44. Since the structure and function of the anti-reflective layer 45 are similar to those of the anti-reflective layer 25 of the first embodiment, so the detailed description thereof will be omitted.

In the present embodiment, the solar cell module 4 further includes a heat-dissipating unit 47, which is disposed on an outer surface 432 of the light-focusing unit 43. The heat-dissipating unit 47 is, for example, a heat-dissipating film, a heat-dissipating plate, a heat pipe, heat sink, or heat fins. Due to the configuration of the heat-dissipating unit 47 and the gel/fluid 42 as well as the metal or alloy light-focusing unit 43, the heat dissipation effect of the solar cell module 4 can be sufficiently enhanced.

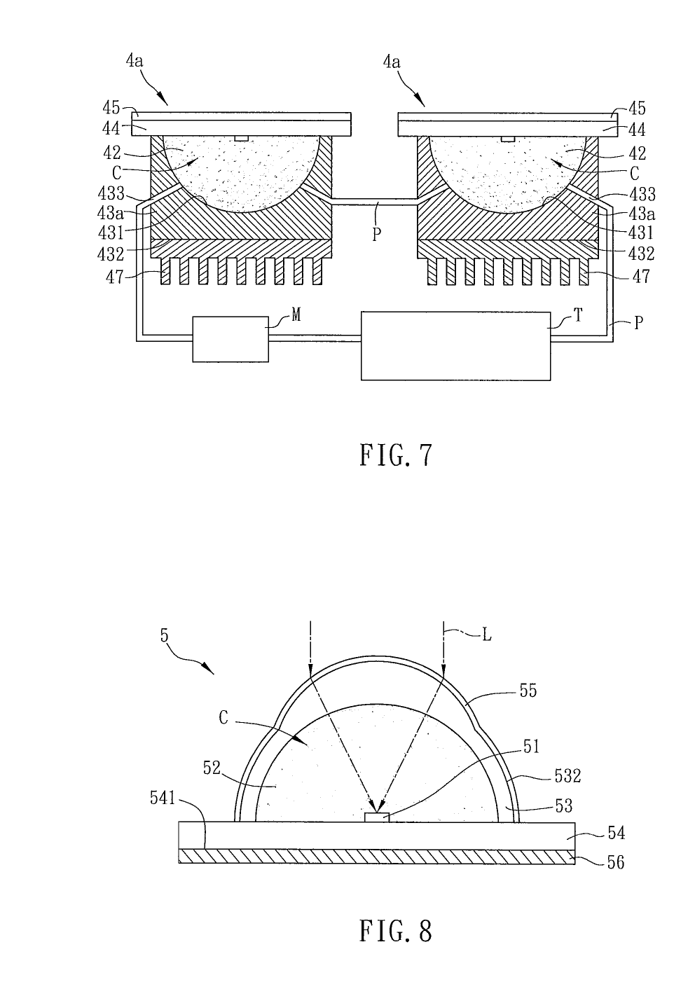

FIG. 7 is a schematic view showing another solar cell module 4a according to the third embodiment of the present invention. As shown in FIG. 7, the light-focusing unit 43a of the solar cell module 4a further has a through hole 433, and a plurality of connecting pipes P are provided to connect a plurality of solar cell module 4a. In addition, the solar cell modules 4a are connected to a motor M and a tank T, so that the fluid 42 in the tank T can be injected into the chambers C through the through holes 433. After filling the chambers C, the through holes 433 are sealed. Alternatively, the through holes 433 may remain open, so that the fluid 42 in the chambers C can absorb heat and then be pumped out by the motor M through the through holes 433, and the fluid 42 in the tank with lower temperature can be pumped into the chambers C. This heat exchange process can further increase the heat dissipation effect of the solar cell modules 4a.

### Fourth Embodiment

FIG. 8 is a schematic view showing a solar cell module 5 according to a fourth embodiment of the present invention. The solar cell module 5 has a chamber C and includes a solar cell device 51, a gel/fluid 52, a light-focusing unit 53 and a carrier 54.

The chamber C is formed by combining the carrier 54 and the light-focusing unit 53. The light-focusing unit 53 is at least partially light-permeable and is disposed at the light entering side, and the solar cell device 51 is disposed on the carrier 54. At least a part of the external light L passes through the light-focusing unit 53 and is then focused on the solar cell device 51.

The structure of the light-focusing unit 53 can be a convex lens or a Fresnel lens. In the present embodiment, the structure of the light-focusing unit 53 is a convex lens for example.

The carrier 54 is at least partially light-permeable and is made of glass, quartz, metal, ceramic material, plastic or polymer. In practice, the carrier 54 can be a transparent substrate or a glass circuit board, and it may have a reflective surface 541 disposed at one side of the carrier 54 facing to or away from the solar cell device 51. At least one part of the external light L is reflected by the reflective surface 541 to the solar cell device 51 for increasing the light utilization. In this embodiment, the carrier 54 is made of transparent material, and a reflective layer 53 is disposed on the reflective surface 541, which is located at one side of carrier 54 away from the solar cell device 51. To be noted, according to different demands, the carrier 54 can have different designs. For example, the carrier 54 may have a plate shape or have a concave portion.

In order to increase the amount of external light L entering into the solar cell module 5, it may further include an anti-reflective layer 55 disposed on a partial surface of light-focusing unit 53. In this embodiment, the anti-reflective layer 55 is disposed on the outer surface 532 of the light-focusing unit 53 for example.

Therefore, the light-permeable light-focusing unit 53 can also focus the external light L to the solar cell device 51 so as to enhance the light utilization of the solar cell module 5. In addition, the light-focusing unit 53 has the convex lens structure for focusing the light beams, so that the applications of the solar cell module 5 can be broadened.

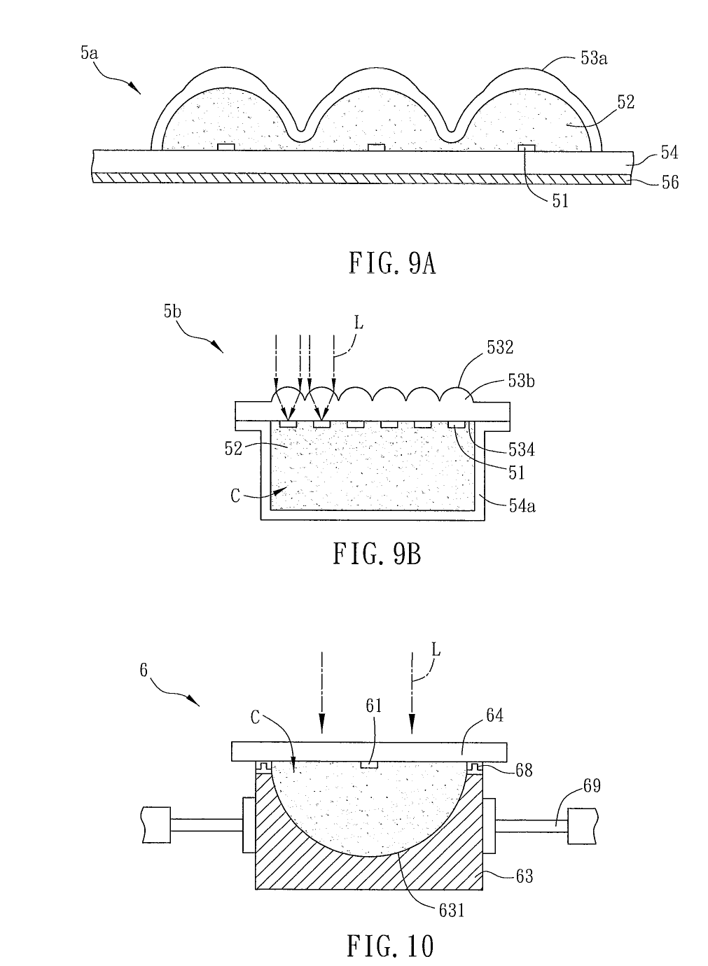

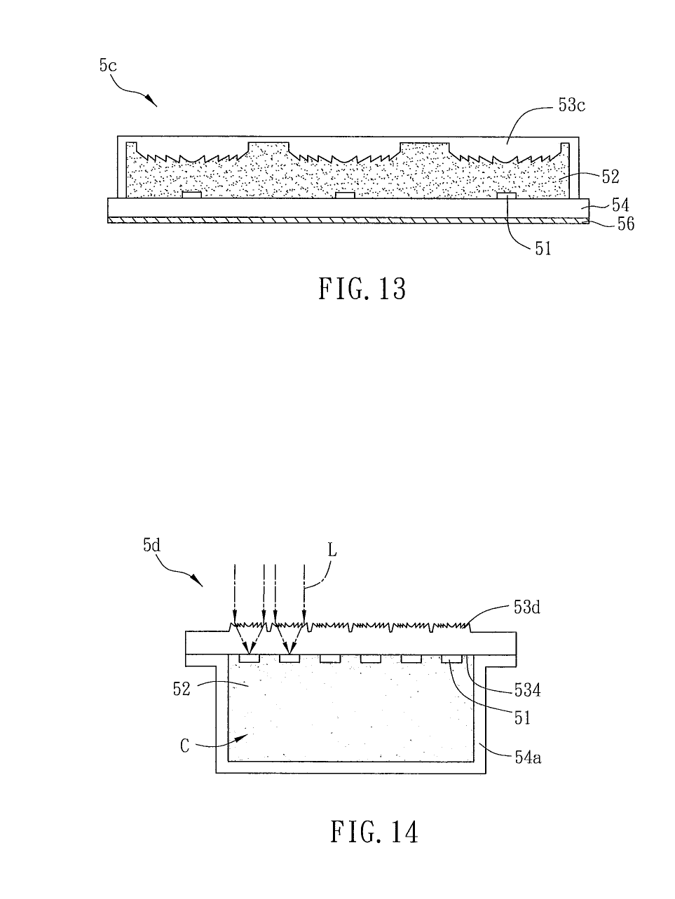

With reference to FIG. 9A, in the solar cell module 5a, a plurality of solar cell devices 51 are disposed on the carrier 54, and the light-focusing unit 53a has a plurality of convex lens structures corresponding to the solar cell devices 51, respectively. This configuration can also increase the photovoltaic conversion efficiency of the solar cell module 5a. To be noted, each convex lens structure can be replaced by a Fresnel lens. As shown in FIG. 13, the light-focusing unit 53c of the solar cell module 5c is a Fresnel lens, which has several Fresnel patterns facing the chamber C and disposed corresponding to the solar cell devices 51, respectively.

FIG. 9B is a schematic view showing another solar cell module 5b according to the fourth embodiment of the present invention. In the solar cell module 5b, the solar cell device 51 is disposed on a surface 534 of the light-focusing unit 53b facing the chamber C. An outer surface 532 of the light-focusing unit 53b has a convex lens structure, and the surface 534 facing the chamber C is a planar surface. The carrier 54a has a concave portion for accommodating the gel/fluid 52. Referring to FIG. 14, the light-focusing unit 53d of the solar cell module 5d is a Fresnel lens, which includes a plurality of Fresnel patterns disposed corresponding to the solar cell devices 51, respectively, for focusing the external light L to the solar cell devices 51. In this embodiment, since the external light L is directly focused to the solar cell devices 51 without passing through the gel/fluid 52, the traveling direction thereof can not be affected by the gel/fluid 52 and thus remains the same.

As mentioned above, the structure design of the solar cell module can be varied depending on the different demands, thereby broadening the applications of the solar cell module of this embodiment.

### Fifth Embodiment

FIG. 10 is a schematic view showing a solar cell module 6 according to a fifth embodiment of the present invention. The solar cell module 6 is different from the previous embodiments in that the light-focusing unit 63 and carrier 64 form the chamber C, and they are relative moveable. In this embodiment, the light-focusing unit 63 and the carrier 64 can be connected by sliding track assemblies 68, which can airtightly combined with each other. Thus, the chamber C can remain in airtight when the light-focusing unit 63 and the carrier 64 are relatively moved. Herein, the carrier 64 can be a glass circuit board or may have a circuit layer.

In addition, the solar cell module 6 may further include a driving assembly 69, which is connected to at least one of the light-focusing unit 63 and the carrier 64, thereby enabling the relative movement of the light-focusing unit 63 and the carrier 64. In this embodiment, the driving assembly 69 is, for example, connected to the light-focusing unit 63. To be noted, the carrier 64 may be fixed by other element to prevent the carrier 64 from moving while the light-focusing unit 63 is driven by the driving assembly 69.

The light-focusing unit 63 has a reflective surface 631 (e.g. a parabolic surface), which can reflect the external light L and focus it on a plane roughly parallel to the carrier 64. If the incident angle of the external light L is changed, the focus of the reflective surface 631 may move accordingly on the plane. In this embodiment, when the driving assembly 69 drives the light-focusing unit 63 to move relative to the carrier 64, the light-focusing unit 63 will change the focal point of the external light L and make the focal point be focused on the solar cell device 61. In addition, since the light-focusing unit 63 and the carrier 64 are connected by the sliding track assemblies 68, the chamber C can remain in airtight when the light-focusing unit 63 and the carrier 64 are relatively moved.

Accordingly, the light utilization of the solar cell module 6 can be effectively increased, and the light-focusing unit 63 and the carrier 64 can relatively moved with respective to the external light L with different incident angles, thereby increasing the working time and applications of the solar cell module 6.

In summary, the solar cell module of the present invention includes a light-focusing unit for focusing at least one part of the external light to the solar cell device, thereby improving the undesired situation that the external light passes through the solar cell module without inducing the photovoltaic conversion in the solar cell device. Thus, the light utilization of the solar cell module can be increased. In addition, the solar cell module of the present invention has a chamber filled with the gel or fluid, so that the heat generated by the solar cell device can be dissipated through the gel or fluid so as to enhance the heat dissipating efficiency of the solar cell device. Furthermore, the structural designs of the light-focusing unit and carrier can be different so as to broaden the applications of the solar cell module of the invention.

Moreover, the solar cell module of the present invention includes the carrier and light-focusing unit, which are relative moveable with respective to the incident direction of the light, so that the light utilization, working time and applications of the solar cell module can be further increased.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A solar cell module having a chamber, the solar cell module comprising:
a solar cell device disposed in the chamber;
a gel or a fluid filled in the chamber; and
a light-focusing unit focusing at least one part of an external light to the solar cell device.

2. The solar cell module according to claim 1, further comprising:
a carrier, wherein the carrier is at least partially light-permeable, and the chamber is positioned in the carrier.

3. The solar cell module according to claim 2, wherein the carrier comprises at least two sub-carriers combined to form the carrier, and the solar cell device is disposed on one of the sub-carriers.

4. The solar cell module according to claim 2, wherein the light-focusing unit is disposed inside the carrier, on an outer surface of the carrier, or separating from the carrier with a gap.

5. The solar cell module according to claim 1, further comprising:
a carrier forming the chamber with the light-focusing unit.

6. The solar cell module according to claim 5, wherein the carrier is at least partially light-permeable, and the external light passes through the carrier.

7. The solar cell module according to claim 5, wherein the light-focusing unit has a reflective surface, and at least one part of the external light passes through the carrier and is then reflected by the reflective surface to the solar cell device.

8. The solar cell module according to claim 5, further comprising:
a heat-dissipating device disposed on the light-focusing unit or the carrier.

9. The solar cell module according to claim 5, wherein the light-focusing unit is at least partially light-permeable, and at least one part of the external light passes through the light-focusing unit and is then focused to the solar cell device.

10. The solar cell module according to claim 5, wherein the solar cell device is disposed in the carrier or the light-focusing unit.

11. The solar cell module according to claim 5, wherein the carrier and the light-focusing unit are relatively moved by a driving assembly.

12. The solar cell module according to claim 11, wherein the light-focusing unit is a tube, a sphere or a pillar.

13. The solar cell module according to claim 11, wherein the light-focusing unit is at least partially light-permeable and has at least one lens structure located at a light input side of the light-focusing unit.

14. The solar cell module according to claim 1, further comprising:
a carrier disposed in the chamber, wherein the solar cell device is disposed on the carrier.

15. The solar cell module according to claim 1, further comprising:
a driving assembly tracking the external light to operating.

16. The solar cell module according to claim 1, wherein the light-focusing unit comprises a Fresnel lens.

17. A solar cell module, comprising:
a carrier;
a light-focusing unit forming a chamber with the carrier; and
a solar cell device disposed in the chamber, wherein the light-focusing unit focuses at least one part of an external light to the solar cell device, and the carrier and the light-focusing unit are relatively moveable.

18. The solar cell module according to claim 17, further comprising:
a driving assembly connecting to the light-focusing unit or the carrier to enable the carrier and the light-focusing unit to be relatively moveable.

19. The solar cell module according to claim 17, wherein the light-focusing unit comprises a Fresnel lens.
